(19) United States
(12) Patent Application Publication
(10) Pub. No.: US 2010/0248383 A1
(43) Pub. Date: Sep. 30, 2010

(54) COMBINED OPTICAL AND ELECTRICAL SENSOR CARTRIDGES

(75) Inventors: Albert Hendrik Jan Immink, Eindhoven (NL); Marc Wilhelmus Gijsbert Ponjee, Sint-Oedenrode (NL); Mark Thomas Johnson, Veldhoven (NL); Murray Fulton Gillies, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/743,833

(22) PCT Filed: Nov. 18, 2008
(86) PCT No.: PCT/IB08/54826

§ 371 Date: May 20, 2010

(30) Foreign Application Priority Data
Nov. 22, 2007 (EP) 07121315.1

(51) Int. Cl. G01N 21/55; G01N 21/05; H05K 13/00

(52) U.S. Cl. 436/164; 422/82.01; 29/592.1

(57) ABSTRACT

A sensor cartridge has a cartridge substrate comprising an optical substrate for optical detection of a target moiety in a sample fluid based on frustrated totalinternal reflection and at least one electric structure. This way, optical read-out and electrical functions, e.g. read-out, are combined in a single substrate, in a simple and cheap manner. Also a method of fabricating such sensor cartridge is provided.

### FIELD OF THE INVENTION

The present invention relates to sensor cartridges, e.g. replaceable or disposable cartridges. More particularly, the present invention relates to sensor cartridges which can provide both frustrated total internal reflection (FTIR) measurements and electrical measurements to be carried out on target moieties in a sample fluid. The present invention furthermore relates to a method for manufacturing such sensor cartridges. The device and method according to embodiments of the present invention can for example be used in molecular diagnostics, biological sample analysis or chemical sample analysis.

### BACKGROUND OF THE INVENTION

Recently frustrated total internal reflection (FTIR) has been proposed as a method to detect the binding of magnetic labels onto a biologically active substrate. Total internal reflection is an optical phenomenon that occurs when a ray of light strikes a medium boundary at an angle larger than the critical angle with respect to the normal to the surface. If the refractive index is lower on the other side of the boundary no light can pass through, so effectively all of the light is reflected. The critical angle is the angle of incidence above which the total internal reflection occurs. A side effect of total internal reflection is the occurrence of an evanescent wave across the boundary surface, an evanescent wave being a near field standing wave exhibiting exponential decay with distance. The decay length may be a few wavelengths distance from the surface 11, for example between 100 and 1000 nm. The presence of nanoparticles (in particular magnetic nanoparticles) in this evanescent wave leads to the phenomenon known as frustrated total internal reflection. The principle of the FTIR read-out method is illustrated in FIG. 1. Systems based on FTIR have demonstrated an ability to detect molecular concentrations approaching the nanomolar level in some test conditions.

An optical substrate 10 is provided, which is preferably injection moulded and has a first major surface 11 onto which magnetic beads 12, e.g. nanobeads having a dimension between 200 and 1000 nm, can be bound. The surface 11 is an optically flat surface that is probed by an evanescent wave 13 that is generated by illuminating the surface 11 from the bottom with a collimated laser or LED light beam 14, generated by a light source 15, the beam 14 illuminating the surface 11 under an angle larger than the critical angle for total internal reflection. When no beads 12 are present the light is reflected from the surface and is collected on an imaging device 16 such as a photo-detector or array detector 16, e.g. a CCD. When beads 12 bind to the surface 11 the evanescent wave 13 is coupled into the beads 12 and is scattered or absorbed and thus lost for detection. Different areas of the surface 11 of the substrate 10 may be made sensitive to different biological species. The amount of light captured by the imaging device 16 will decrease in proportion to the number of beads 12 bound to the surface 11.

An electromagnet 17 may be provided for attracting the magnetic beads 12, and/or for removing non-bound beads 12 before performing a measurement step.

The optical substrate 10 for FTIR detection is very convenient for several reasons:
It is simple and very cheap. It can be made in large quantities, for example by simple injection moulding.
It can be made of polystyrene material, which is the same material as that commonly used for well-plates. In this way an assay developed in a well-plate can be transferred more easily to a disposable point-of-care-cartridge.

However, it also has a disadvantage: it has a limited functionality. The cartridge only enables optical detection of target moieties. Sometimes optical detection per se is not sufficient.

### SUMMARY OF THE INVENTION

It is an object of embodiments of the present invention to provide improved sensor cartridges with an optical substrate for optical FTIR detection, which sensor cartridges can be manufactured by a low-cost manufacturing technology.

The above objective is accomplished by a method and device according to the present invention.

In a first aspect, the present invention provides a sensor cartridge having a cartridge substrate comprising an optical substrate for optical detection of a target moiety in a sample fluid based on frustrated total internal reflection and at least one electric structure.

It is an advantage of embodiments of the present invention that a cheap and simple sensor cartridge, e.g. biosensor cartridge, is obtained that combines optical read-out and electrical functions, e.g. read-out, in a single substrate. The optical read-out may in particular be FTIR.

In a sensor cartridge according to embodiments of the present invention, the at least one electric structure may be provided on an optically flat surface of the optical substrate. This way, passive electrodes can be deposited on the optical substrate.

The optical substrate may be injection moulded. Injection moulding has the advantage that it is a proper method to make a very cheap disposable cartridge.

In a sensor cartridge according to embodiments of the present invention, a transparent electronics substrate may be provided between the optical substrate and the at least one electric structure. An electronic device, such as e.g. a GMR sensing element, may be integrated in the transparent electronics substrate. The electronic device may be connected to the at least one electric structure on the transparent electronics substrate. The transparent electronics substrate may be glued to the optical substrate by means of an optical glue.

The at least one electric structure may be a patterned electrode layer. Alternatively, the at least one electric structure may be in the form of a thin film substrate.

A sensor cartridge according to embodiments of the present invention may furthermore comprise a fluidics part on top of the cartridge substrate. A fluidic channel may be formed in the fluidics part.

The fluidics part may be injection moulded, injection moulding being a cheap and easy way to obtain such fluidics part.

In a sensor cartridge according to embodiments of the present invention, the fluidics part may be assembled on top of the cartridge substrate by means of a double-sided tape. The fluidic channel may be formed in the tape.

A sensor cartridge according to embodiments of the present invention comprises the optical substrate and the at least one electric structure assembled together on opposite sides of a fluidic channel.

Biological binding layers may be provided on the optical substrate and other biological reagents, such as e.g. dried nanoparticle labels or dry buffer reagents, may be provided on the opposite sides of the fluidic channel on an electric substrate.

A sensor cartridge according to such embodiment comprises at least two substrates having different functionalities. The two substrates have distinct different technological processing, with optionally minimal, and preferably no, additional processing steps for the surface that is biologically functionalised.

A double-sided tape may be provided between the optical substrate and an electrical substrate carrying the at least one electric structure. A fluidic channel may be formed in the tape. Alternatively, a fluidic channel may be provided in or on the electrical substrate, for example via injection moulding or via patterning a resist layer. According to still an alternative embodiment, a fluidic channel is provided in the optical substrate, for example via injection moulding.

In a further embodiment, a sensor cartridge is provided, wherein a biologically active layer is deposited on the optical substrate.

In a second aspect, the present invention provides a sensor comprising a sensor cartridge according to embodiments of the present invention, a light source for providing a beam of light onto an optically flat surface of the optical substrate of the sensor cartridge under an angle which is larger than the critical angle for total internal reflection, and an optical detector for detecting a portion of the beam of light which is reflected on the optically flat surface. The sensor may furthermore comprise driving means for driving the at least one electric structure.

In a third aspect, the present invention provides a method for fabricating a sensor cartridge, the method comprising providing at least one electrical structure on an optical substrate adapted for FTIR detection.

Providing the at least one electrical structure may comprise providing the at least one electrical structure on an optically flat surface of the optical substrate, e.g. by sputtering.

Alternatively, providing the alt least one electrical structure may comprise providing the at least one electrical structure on an electronics substrate, and attaching the electronics substrate to the optical substrate. Attaching the electronics substrate to the optical substrate may be performed so as to provide a fluidic channel between the optical substrate and the electronics substrate.

A method according to embodiments of the present invention may furthermore comprise providing an electronic device, e.g. a GMR sensor chip or temperature sensor element, on or in the electronics substrate.

A method according to embodiments of the present invention may furthermore comprise providing a fluidic part comprising a fluidic channel onto the optical substrate.

In a fourth aspect, the present invention provides the use of a sensor cartridge according to embodiments of the present invention for combined optical detection of target moieties in a fluid sample and electrical handling of the fluid sample. The optical detection may be FTIR detection.

In embodiments of the present invention, the electrical handling may be electrical detection of target moieties in the fluid sample.

In embodiments of the present invention, the electrical handling of the fluid sample may comprise any of heating of fluid sample or movement of beads in fluid sample.

In a fifth aspect, the present invention provides a method of determining target moieties in a fluid sample, the method comprising measuring an optical characteristic of the fluid sampling and performing an electrical action on the fluid sample.

In a sixth aspect, the present invention provides a disposable device comprising a sensor cartridge according to an embodiment of the present invention.

In a further aspect, the present invention provides a reader device adapted for receiving a combined optical and electrical cartridge as in any of the cartridge embodiments of the present invention. The reader device comprises a light generator, a detector for FTIR read-out and electronic control and measurement means to be used in combination with the at least one electric structure in the cartridge.

Particular and preferred aspects of the invention are set out in the accompanying independent and dependent claims. Features from the dependent claims may be combined with features of the independent claims and with features of other dependent claims as appropriate and not merely as explicitly set out in the claims.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 illustrates the principle of magnetic label detection via frustrated total internal reflection (FTIR) as known from the prior art.

FIG. 2 illustrates an embodiment of the present invention, where a patterned metallic layer is provided onto an optical substrate.

FIG. 3 illustrates combination of a large-area electronics-on-glass technology and an optical read-out substrate, according to an embodiment of the present invention.

FIG. 4 illustrates an embodiment of the present invention, where a GMR chip is integrated in an electronic substrate provided on an optical substrate.

FIG. 5 shows a 3D artist impression of a drop-in device in an electrically active substrate in accordance with embodiments of the present invention.

FIG. 6 shows a cross-section of a sensor cartridge with a silicon chip (e.g. GMR chip) mounted in the optical substrate as a drop-in device, in accordance with an embodiment of the present invention.

FIG. 7 illustrates a sensor cartridge comprising an optical substrate and a ‘large-area-electronics’ glass top part, assembled together on opposite sides of a microfluidics channel, in accordance with an embodiment of the present invention.

FIG. 8 illustrates a combination of an optical substrate and an electrical top-part containing a (silicon) chip, in accordance with an embodiment of the present invention.

FIG. 9 illustrates a combination of an optical substrate with a plastic top part comprising electrodes, according to an embodiment of the present invention.

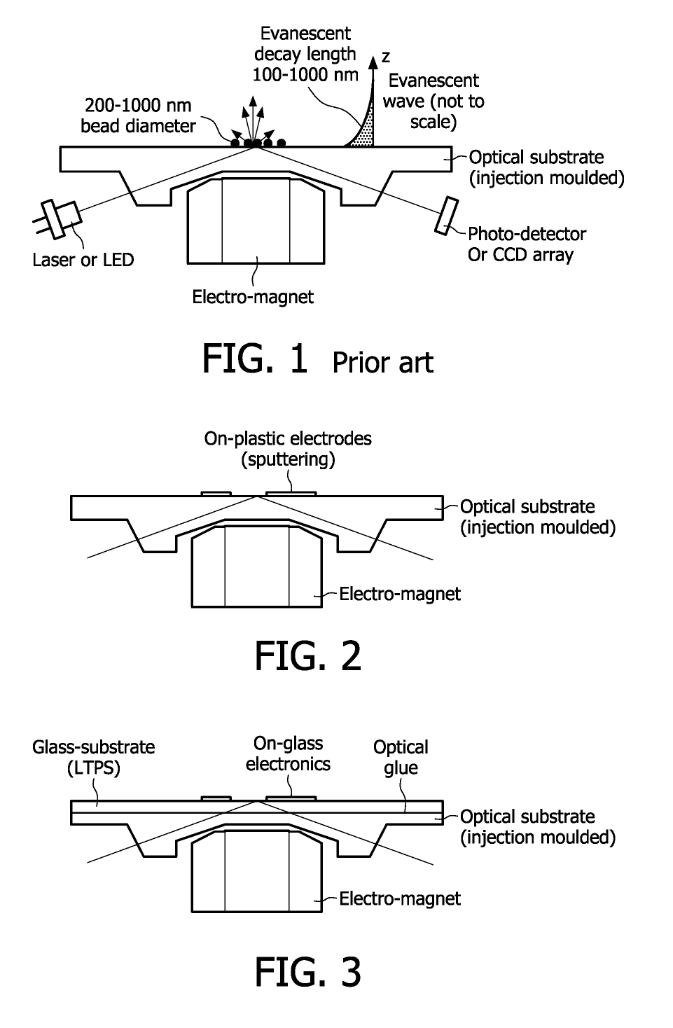

In the different figures, the same reference signs refer to the same or analogous elements.

### DETAILED DESCRIPTION OF EMBODIMENTS

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes.

Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

The following terms or definitions are provided solely to aid in the understanding of the invention. The definitions should not be construed to have a scope less than understood by a person of ordinary skill in the art.

The term “probe” relates in the present invention to a binding molecule that specifically binds a target moiety. Probes envisaged within the context of the present invention include biologically-active moieties such as but not limited to whole anti-bodies, antibody fragments such as Fab′ fragments, single chain Fv, single variable domains, VHH, heavy chain antibodies, peptides, epitopes, membrane receptors or any type of receptor or a portion thereof, substrate-trapping enzyme mutants, whole antigenic molecules (haptens) or antigenic fragments, oligopeptides, oligonucleotides, mimitopes, nucleic acids and/or mixture thereof, capable of selectively binding to a potential target moiety. Antibodies can be raised to non-proteinaceous compounds as well as to proteins or peptides. Probes are typically members of immunoreactive or affinity reactive members of binding-pairs. The nature of the probe is determined by the nature of the target moiety to be detected. Most commonly, the probe is developed based on a specific interaction with the target moiety such as, but not limited to, antigen-antibody binding, complementary nucleotide sequences, carbohydrate-lectin, complementary peptide sequences, ligand-receptor, coenzyme, enzyme inhibitors-enzyme, etc. In the present invention, the function of a probe is to specifically interact with a target moiety to permit its detection. Therefore, the probes are attached to nanoparticle objects, which can be magnetic or magnetizable objects such as magnetic particles. The probe can be an anti-analyte antibody if, for instance, the target moiety is a protein. Alternatively, the probe can be a complementary oligonucleotide sequence if, for instance, the target moiety is a nucleotide sequence.

In a first aspect of the present invention a sensor cartridge is provided for determining the presence and/or amount of target moieties in a sample fluid. The sensor cartridge comprises an optical substrate adapted for optical detection based on frustrated total internal reflection (FTIR) of a target moiety in a sample fluid, and at least one electric structure. The optical substrate is a transparent substrate with a refractive index which is higher than the refractive index of the material surrounding the transparent substrate, for example air or sample liquid. The optical substrate may for example be made of glass, polystyrene or PMMA. The optical substrate may be provided with one or more probes for specifically binding target moieties. In embodiments of the present invention, the electric structure may be an electric structure for electrical detection of properties of the sample fluid, such as e.g. electro-chemical detection or electrolyte detection. In embodiments of the present invention, the electric structure may be passive electrode structures for auxiliary electric systems, such as e.g. wetting detection (resistive, capacitive), joule heating of the sample fluid, fluid temperature measurements, micro-magnetic actuation for moving beads from one place to the other, active or passive matrix structures for driving or read-out of arrays with limited pin-out. In embodiments of the present invention, the electric structure may be active electronic structures for example comprising special sensor elements, e.g. a GMR sensor chip, or electronic processing. In embodiments of the present invention, driving means for driving the at least one electric structure may be provided. The driving means may include a controller pre-programmed for applying a pre-determined driving scheme to the at least one electric structure.

In embodiments of the present invention, the at least one electric structure may be used for electrical detection. Performing electrical detection may be advantageous in several commonly used detection technologies in point-of-care devices, e.g. cardiac tests:
Electro-chemical detection (Redox reactions).
Electrolyte detection (via ion-selective membranes).

Furthermore, in alternative embodiments of the present invention, simple auxiliary systems may be more easily realized using (passive) electrodes or even active in-cartridge electronics:
Wetting detection (resistive, capacitive).
Joule heating of the fluid.
Fluid temperature measurements.
Micro-magnetic actuation for moving beads from one place to the other.
Matrix structures (passive, active) for driving or read-out of arrays with limited pin-out.

A first embodiment of a method to provide an electric structure in a sensor cartridge suitable for FTIR read-out is to deposit a patterned conductive, e.g. metallic, layer 20 onto the optically flat surface 11 of the optical substrate 10. This way, passive electrodes can be deposited on the optical, e.g. plastic, substrate 10. The patterned conductive layer 20 may be provided in direct contact with the optically flat surface 11 of the optical substrate 10. This is shown schematically in FIG. 2. Such a patterned electrode layer 20 can for example be made by sputter deposition via a shadow mask that is pressed onto the optically flat surface (also called contact-mask; a form of photolithography whereby the image to be printed is obtained by illumination of a photomask in direct contact with a substrate coated with an imaging photoresist layer). With this technology linewidths down to about 10 μm are obtainable.

The advantage of a method according to this first embodiment as illustrated in FIG. 2 is that it is rather cheap and simple. Therefore, the devices obtained are cheap as well, hence very convenient for disposable items, such as some types of biosensor devices. Disadvantages may be that only passive structures can be made (i.e. only electrodes and no active electronics) and that the resolution is limited (to about 10 μm).

In a further embodiment this can be solved by combining a large-area electronics technology with the earlier proposed optical substrate 10. Large-Area Electronics are electronic devices fabricated on a thin substrate, e.g. glass substrate, optionally a flexible substrate. This substrate is called further on the “electronics substrate”. Large electronic circuits made with thin-film transistors and other devices can be easily patterned onto large substrates, which can be up to a few meters wide and, if flexible, a few km long. Some of the devices can be patterned directly, much like an inkjet printer deposits ink. For most semiconductors, however, the devices must be patterned using photolithography techniques.

An example is shown in FIG. 3. The electronics 30 may be (high resolution) passive electronics, but may also comprise active electronic devices such as transistors, diodes and photodiodes. An LTPS (low-temperature polysilicon) process may be used to manufacture active electronic structures on a thin transparent, e.g. glass, substrate 31 (thickness in the order of 0.4 mm). Alternatively, other technologies could be used to realise the large area electronics 30, for example amorphous-Si (a-Si), microcrystalline Si, CdSe or organic semiconductor based thin film transistor (TFT) technologies, diode based technologies (such as PIN or Shottky diodes) or metal-insulator-metal (MIM) diode technologies.

The transparent electronics substrate 31 is glued, e.g. with a transparent, refractive-index-matched glue 32, to an optical substrate 10 adapted for optical (FTIR) read-out. The optical substrate 10 may for example be injection moulded. As a glue 32, known optical glues can be chosen, such as for example an UV-curing polymer. The refractive index of the material of the electronics substrate, e.g. glass, and the refractive index of the material of the optical substrate, e.g. plastic, can be matched in order to prevent optical aberration or refraction at the interface between the optical substrate 10 and the electronics substrate 31.

In a further embodiment (not illustrated in the drawings), the electronics may be in the form of a thin film substrate, such as a polyimide substrate, which is preferably realised by a release or a transfer technology from a carrier plate such as a glass carrier plate—examples are the Philips EPLAR technology and the Suftla technology from Seiko-Epson. The thin film substrate, e.g. polyimide substrate, may also include optical structures for in and out-coupling of light. In accordance with embodiments of the present invention, the thin film substrate is applied to the optically flat surface 11 of the optical substrate 10.

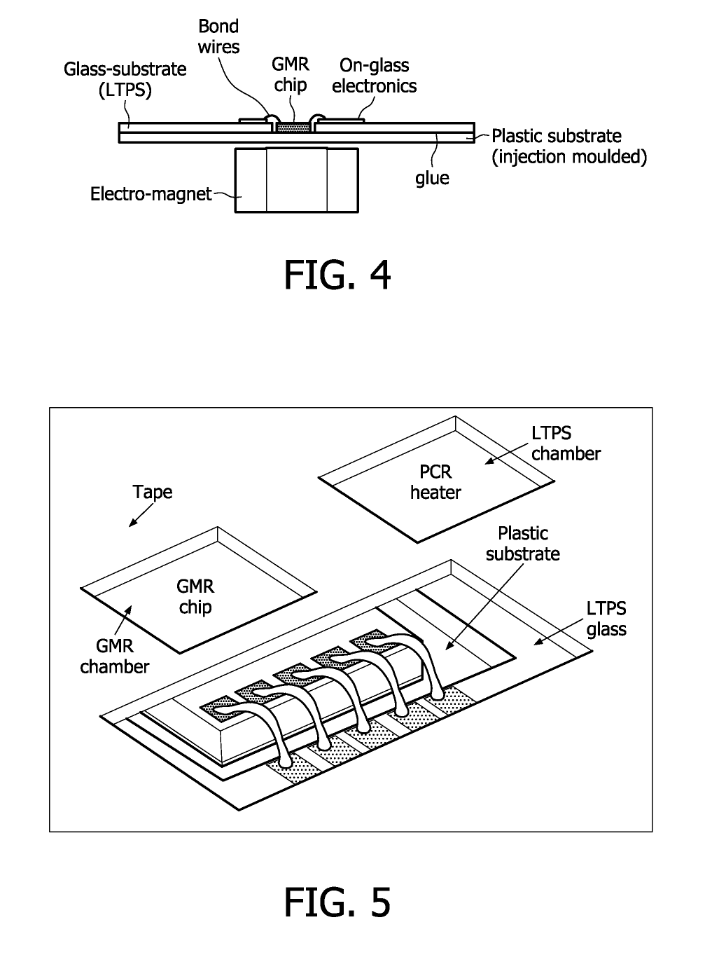

In a further embodiment where special sensor elements or electronic processing is needed in a sensor cartridge, e.g. a biosensor cartridge, a separate device 40 (e.g. a GMR sensor chip) can be integrated in the electronics substrate 31, which may be a transparent, e.g. glass substrate. For this purpose a small hole is made in the substrate 31, for example by etching or mechanical tooling. In the hole the separate device 40 is placed. The device 40 can be connected via wire-bonding 41 to the rest of the electrical circuitry 30 on the electronics substrate 31 of the cartridge. An example is shown in FIG. 4.

In an alternative embodiment (not explicitly illustrated in the drawings), the separate device may be attached to the surface of the electronics substrate, e.g. glass substrate, using a flip-chip, chip-on-glass or other surface mounting technology, or may be connected via a connection foil.

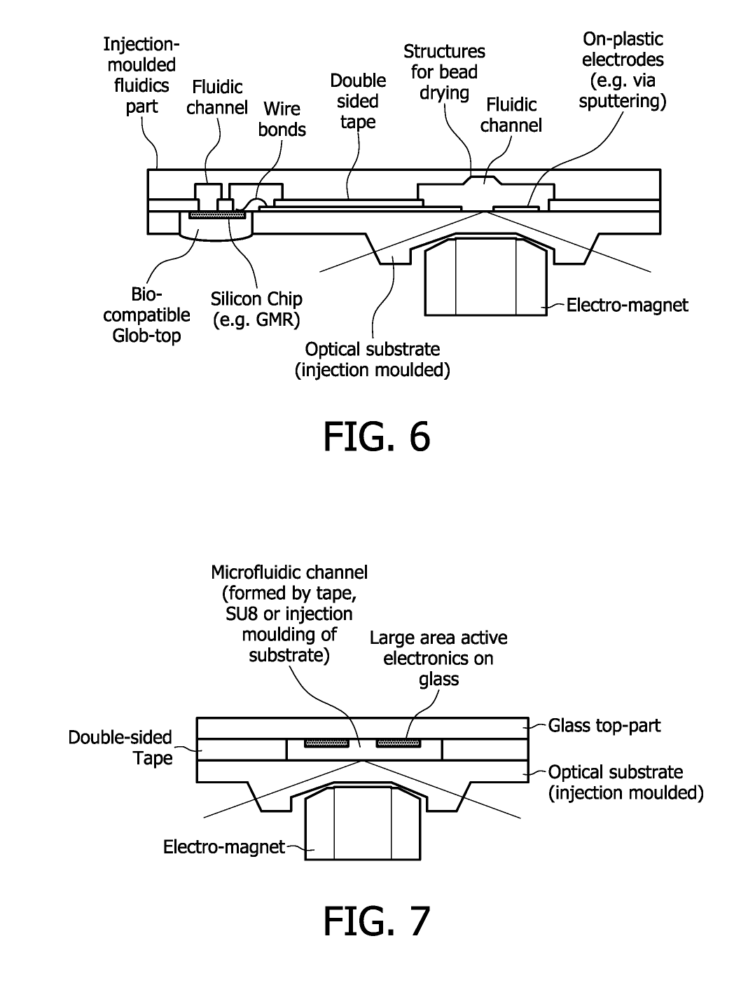

In accordance with embodiments of the present invention, as illustrated in FIGS. 6 to 9, a fluidics part 60 comprising fluidics channels 61 and/or chambers may be provided on the combined optical/electric sensor cartridge substrate as described above with respect to embodiments of the present invention. A double-sided tape 50 can be used to assemble the fluidics part 60 on top of the sensor cartridge substrate 10, 31 according to embodiments of the present invention. This tape 50 can be patterned in such a way that the fluidics channels 61 are separated from electric or electronic connections (e.g. the bond-wires 41) where needed. A 3D artist impression of a drop-in chip 40 in electrical substrate technology is shown in FIG. 5. This example envisions a GMR sensor chamber 51 and a PCR (polymerase chain reaction) chamber 52 with controlled heating in a same disposable sensor cartridge comprising an optical substrate 10 for FTIR sensing and at least one electric structure 31, 40, according to an embodiment of the present invention.

In yet another embodiment the electronic device 40, such as a GMR sensor chip or a processing element, may be provided into the optical, e.g. plastic, substrate 10 itself, rather than in an electronic substrate 31. A cavity or through-substrate-hole can be made in the optical, e.g. plastic, substrate 10. The electronic device, e.g. chip 40, can be dropped in and wire-bonded by means of wire bonds 41 to a conductive, e.g. metal, lead-frame 20 that is deposited on the optical substrate 10, which may be injection moulded, and functions as a carrier. Deposition of the conductive lead-frame 20 on the optical substrate may be performed by any suitable deposition method, e.g. via sputtering or evaporation or wave-printing, etc. The electronic device 40, e.g. chip, can be mounted in the optical, e.g. plastic, substrate 10 by using a glob-top material 62. This may for example be performed by placing the optical substrate 10 which is provided with a through-substrate-hole top-down with its optically flat surface 11 on another flat surface, dropping in the electronic device 40, e.g. chip, and filling the hole with glob-top material 62. Where the glob-top material will come into contact with sample fluid, a bio-compatible glob-top material may be used (an example is Namics Chipcoat 8462-21) FIG. 6 shows a cross-section of an embodiment of a cartridge according to embodiments of the present invention, with an optical substrate 10 adapted for FTIR measurements and a drop-in electronic device 40, e.g. a silicon chip such as a GMR sensor chip, in the optical substrate 10. By using double-sided tape 50 for connecting the fluidics part 60 to the combined optical/electrical substrate 10, 20 according to embodiments of the present invention, the wire-bonds 41 can be separated from the fluidic channel 61.

The combination of electrical and optical detection in a single hybrid cartridge in accordance with embodiments of the present invention has many advantages:
Point-of-care detection technologies can be combined: e.g. a magnetic-label immuno-assay can be combined with electrochemical detection of cholestorol.
Assay device methods such as wetting detection or controlled heating can be integrated into a cartridge suitable for optical detection of magnetic labels. Controlled heating can for example be made by combining Joule heaters and temperature sensors on a large-area electronics substrate, e.g. a large-area electronics-on-glass substrate. Applications are for example in controlling the assay temperature or integrated PCR for DNA/RNA amplification.
Integrated micro-magnetic actuation can be performed, e.g. moving beads from one chamber to the next via 3-phase driving of electrode structures (conveyor belt structures), or making a bead mixer in a chamber by a radially organized electrode structure.
The number of output/input pins of the sensor cartridge can be kept limited due to active electronics in the cartridge integrated onto the substrate. For example the controlled heating using an array of heaters and temperature sensors can be driven by multiplexing electrical signals on a same pin, or via matrix driving technologies (active/passive matrices).

In all the embodiments of the present invention, electrical functionality is added to an optical substrate 10 adapted for performing optical measurements based on FTIR.

In all of the above-described embodiments, however, the sensor substrate 11 is subject to processing (comprising one or more chemical or physical processing steps). The bottom optical, e.g. plastic, substrate 10 is also the substrate for binding biologic layers (such as oligo's, antibodies, enzymes, etc.). Binding can take place via various mechanisms such as for example covalent binding and physical adsorption (e.g. via charge). The binding of the biological agents (both specific and a-specific) is generally very sensitive to the properties of the substrate. Also the hydrophobic/hydrophylic properties of the substrate generally need to be tuned in order to get a proper microfluidic flow in the cartridge. For this reason it is advantageous if additional processing of the substrate 10 would be minimized. This means that it is advantageous if, after the initial provision, e.g. by injection moulding, of the substrate 10, as little additional processing as possible is provided. The optical substrate may be provided with one or more probes for specifically binding target moieties.

A solution to the problem of having as little additional processing to the optical substrate 10 as possible is to combine an optical substrate 10 for FTIR measurements with at least one electric structure or element into a single device by assembling them together on opposite sides of a fluidic channel. This assembling can be done in any suitable way, for example by gluing or by using double-sided tape. This way, different technologies and different functionalities are assembled together. The optical substrate 10 can comprise the biological binding sites for binding nano-particle labels via specific biological coupling. The electric structure or element assembled on suitable substrates on the opposite sides of the fluidic channel may comprise other biological components such as dried buffer reagents, or (freeze) dried functionalized nanoparticle labels. The electric structure or element may be used to improve redispersion of the nanoparticle labels by generating suitable magnetic or electrical fields. Furthermore the electric structure or element may be used for detecting the redispersion efficiency of the nanoparticle labels or the dry reagents (e.g. by resistance or capacitance measurements).

In one embodiment, shown in FIG. 7 an optical substrate 10 is combined with a ‘large-area-electronics’ (LAE) top part 31, e.g. a glass top part. Both optical substrate 10 and electric substrate 31 are assembled together by means of a double-sided tape 50. The fluidic channel structures 61 can be formed in the tape 50, for example by laser-cutting the tape 50. In an alternative embodiment, not illustrated in FIG. 7, the optical substrate 10 and the large-area-electronics top part 31 can be assembled together, e.g. glued together by means of a suitable adhesive which can be provided with sufficient thickness for it to allow it to be provided with one or more microfluidic channels 61. Such adhesives may for example be photoresist type of materials, for example epoxy resins, e.g. SU8, which may be provided for example by spin-coating and which can be provided with microfluidic channels 61 by means of illumination through a mask with a desired pattern and developing, e.g. curing or cross-linking the photoresist type of material. In yet another embodiment, not illustrated in FIG. 7, the fluidic channel structures 61 can be formed in the optical substrate 10, e.g. during formation of the optical substrate 10, e.g. during injection moulding thereof, and the optical substrate 10 with fluidic channel may be attached, e.g. glued, to the large-area-electronics top part 31.

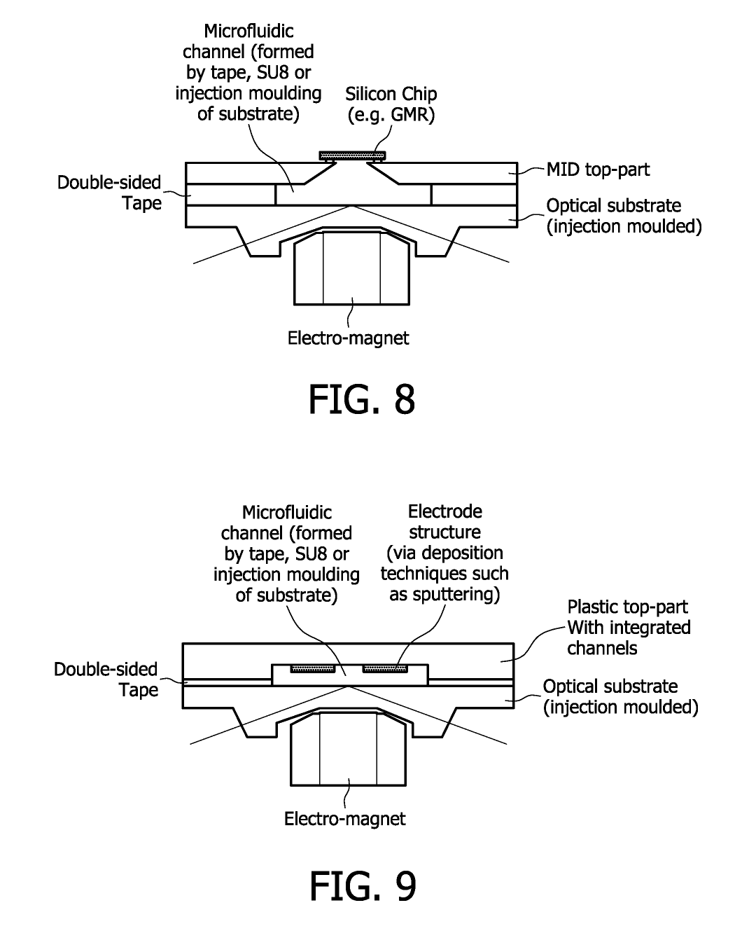

Several other combinations are also possible according to embodiments of the present invention. In FIG. 8 a combination of an optical substrate 10 and an electrical substrate 80 containing an electronic device such as a silicon chip, e.g. a GMR chip 40, is shown. The electronic device 40 may be provided in or on the electrical substrate 80. The microfluidic channel 61 in FIG. 8 is formed by the double-sided tape 50 used for assembling the optical substrate 10 and the electronic substrate 80. It can however also be formed by injection moulding of the optical substrate 10 or by patterning a resist (e.g. SU8) onto one of the substrates 10, 80, preferably on the electrical substrate 80.

In yet a further embodiment, illustrated in FIG. 9, an optical substrate 10 is shown with a top-part 90, e.g. a plastic top-part, comprising electrodes 91 and a microfluidic channel 61. The top-part 90 may be injection moulded so as to provide the fluidic channel 61. A biologically active layer can be deposited on the optical substrate 10, which may also be injection moulded. This can for example be done via inkjet printing. The optical substrate 10 can be made of a suitable polymer (e.g. polystyrene) that is favourable for binding biological agents. The top part 90 may be attached to the optical substrate 10 in any suitable way, for example by means of a suitable adhesive. Alternatively, a double-sided tape 50 may be used, which is patterned to be conform with the fluid channels 61 in the top-part 90.

It is to be noted that the embodiments shown and discussed are not an exhaustive list of the possibilities of embodiments according to the present invention. Another combination of functional substrates is also possible, where the substrate targeted for biological binding is subject to minimal (or no) processing to generate further detection functionality. Processing to improve biological binding (such as cleaning, chemical functionalisation, charging, hyrophylisation/hydrophobisation) is of course still possible for the binding surface.

For all embodiments in accordance with the present invention, the electronics on the top substrate may be (high resolution) passive electronics, but in alternative embodiments may comprise active electronics devices such as transistors, diodes and photodiodes. For example an LTPS (low-temperature poly silicon) process could be used to manufacture active electronic structures on an electronics substrate, e.g. a glass substrate. Alternatively, other technologies could be used to realise the large area electronics, for example amorphous-Si (a-Si), microcrystalline Si, CdSe or organic semiconductor based thin film transistor (TFT) technologies, diode based technologies (such as PIN or Shottky diodes) or metal-insulator-metal (MIM) diode technologies. In general, the LAE technologies may be applied to rigid (glass, plastic) and flexible (metal, plastic film, polyimide) substrates.

Examples of the functionalities that can be integrated in the top substrate (electronics substrate) include heaters for PCR and performing melting curves, current coils for magnetic field generation, electrodes for E-field generation, photodiodes to measure optical signals, electrodes for controlling micro fluidic pumps and valves etc. These examples do not in any way exclude any non-listed functionalities which may also be incorporated in the top substrate.

It is to be understood that although preferred embodiments, specific constructions and configurations, as well as materials, have been discussed herein for devices according to the present invention, various changes or modifications in form and detail may be made without departing from the scope of this invention as defined by the appended claims.

1. A sensor cartridge having a cartridge substrate comprising an optical substrate (10) for optical detection of a target moiety in a sample fluid based on frustrated total internal reflection and at least one electric structure.

2. A sensor cartridge according to claim 1, wherein the at least one electric structure (20, 30) is provided on an optically flat surface (11) of the optical substrate (10) and wherein the optical substrate is injection molded, there being a transparent electronics substrate (31) between the optical substrate (10) and the at least one electric structure (30), and an electronic device (40) integrated in the transparent electronics substrate (31).

3. A sensor cartridge according to claim 2, wherein the electronic device (40) is a GMR sensing element and wherein the electronic device is connected to the at least one electric structure on the transparent electronics substrate (31), wherein the transparent electronics substrate is glued to the optical substrate by means of an optical glue, and wherein the at least one electric structure is a patterned electrode layer.

4. A sensor cartridge according to claim 1, furthermore comprising a fluidics part (60) on top of the cartridge substrate (10, 20; 10, 31, 30; 10, 31, 30, 40), wherein a fluidic channel (61) is formed in the fluidics part (60), and wherein the fluidics part is injection moulded, and wherein the fluidics part (60) is assembled on top of the cartridge substrate (10, 20; 10, 31, 30; 10, 31, 30, 40) by means of a double-sided tape (50) wherein the fluidic channel (61) is formed in the tape (50).

5. A sensor cartridge according to claim 1, wherein the optical substrate (10) and the at least one electric structure (20, 30) are assembled together on opposite sides of a fluidic channel (61), wherein biological binding layers are provided on the optical substrate (10) and other biological reagents are provided on the opposite sides of the fluidic channel (61) on an electric substrate (31), wherein driving means for driving the at least one electric structure are comprised.

6. A sensor cartridge according to claim 4, wherein a double-sided tape (50) is provided between the optical substrate (10) and an electrical substrate (30) carrying the at least one electric structure (30), wherein a fluidic channel (61) is formed in the tape (50), and wherein a fluidic channel is provided in or on the electrical substrate or alternatively in the optical substrate.

7. A sensor comprising a sensor cartridge according to claim 1, a light source for providing a beam of light onto an optically flat surface (11) of the optical substrate (10) of the sensor cartridge under an angle which is larger than the critical angle for total internal reflection, and an optical detector (16) for detecting a portion of the beam of light which is reflected on the optically flat surface (11).

8. A method for fabricating a sensor cartridge, the method comprising providing at least one electrical structure on an optical substrate adapted for FTIR detection.

9. A method according to claim 8, comprising providing the at least one electric structure on an optically flat surface (11) of the optical substrate.

10. A method according to claim 8, comprising providing the at least one electrical structure on an electronics substrate, and attaching the electronics substrate to the optical substrate, wherein attaching the electronics substrate to the optical substrate is performed so as to provide a fluidic channel between the optical substrate and the electronics substrate, furthermore comprising providing an electronic device on or in the electronics substrate

11. A method according to claim 8, furthermore comprising providing a fluidic part comprising a fluidic channel onto the optical substrate.

12. Use of a sensor cartridge according to claim 1 for combined optical detection of target moieties in a fluid sample and electrical handling of the fluid sample.

13. A method of determining target moieties in a fluid sample, the method comprising measuring an optical characteristic of the fluid sample and performing an electrical action on the fluid sample.

14. A disposable device comprising a sensor cartridge according to claim 1.

15. A reader device adapted for receiving a combined optical and electrical cartridge as in claim 1, comprising a light generator and a detector for FTIR read-out and electronic control and measurement means to be used in combination with the at least one electric structure in the cartridge.
